(19) United States
(12) Patent Application Publication
(10) Pub. No.: US 2013/0099776 A1
(43) Pub. Date: Apr. 25, 2013

(54) WIRELESS CHARGING INTENSITY INDICATION METHOD AND CHARGED DEVICE

(71) Applicant: Huawei Technologies Co., Ltd., Shenzhen (CN)

(72) Inventors: Hao Wu, Shenzhen (CN); Kangmin Huang, Shenzhen (CN); Yulin Zheng, Shenzhen (CN); Haitao Ding, Shenzhen (CN)

(73) Assignee: Huawei Technologies Co., Ltd., Shenzhen (CN)

(21) Appl. No.: 13/626,042

(22) Filed: Sep. 25, 2012

Related U.S. Application Data
(63) Continuation of application No. PCT/CN2012/073133, filed on Mar. 27, 2012.

(30) Foreign Application Priority Data
Sep. 27, 2011 (CN) 201110296809.X

(51) Int. Cl. G01R 19/145

(52) U.S. Cl. 324/133

(57) ABSTRACT

The present invention discloses a wireless charging intensity indication method, including: obtaining, by a charged device, wireless charging intensity of the charged device at a present charging position, and displaying, on a display screen, the wireless charging intensity at the present charging position, where the displaying the wireless charging intensity on the display screen is intended to provide a basis for a user to select an optimum charging position. By using the wireless charging intensity indication method provided by the embodiment of the present invention, the user may select, from different charging positions, the optimum charging position according to the magnitude of the wireless charging intensity displayed on the display screen of the charged device, thereby improving the efficiency of wireless charging. The embodiments of the present invention also provide a corresponding charged device and a mobile terminal.

### CROSS-REFERENCE TO RELATED APPLICATIONS

This application is a continuation of International Application No. PCT/CN2012/073133, filed on Mar. 21, 2012, which claims priority to Chinese Patent Application No. 201110296809.X, filed on Sep. 27, 2011, both of which are hereby incorporated by reference in their entireties.

### TECHNICAL FIELD

The present invention relates to the field of wireless charging technologies, and in particular, to a wireless charging intensity indication method and a charged device.

### BACKGROUND

As a technology emerging in recent years, wireless charging can supply power to a charged device in a wireless mode. The principle of wireless charging is as follows. A wireless charging device includes one or more transmitting coils that can transmit electrical energy in a wireless mode, and the charged device has at least one receiving coil that can receive the electrical energy, so that wireless charging is implemented.

One or more charged devices may be placed on one wireless charging device, and wireless charging may be provided for the one or more charged devices at one time. Because the distance, direction, and size of the receiving coil of the charged device relative to the transmitting coil of the wireless charging device are different, the efficiency of wireless charging is different, that is, if the charging position of the charged device on the wireless charging device is different, the efficiency of wireless charging is different.

In the prior art, by drawing up in advance the optimum charging position and direction of the charged device on the wireless charging device, the charged device determines the charging position according to the indication. However, because charging devices are diversified, the indication method lacks adaptability.

### SUMMARY

Embodiments of the present invention provide a wireless charging intensity indication method, so that it is convenient for a user to find an optimum charging position, and the efficiency of wireless charging can be improved. A corresponding charged device is also provided.

A wireless charging intensity indication method includes:

obtaining, by a charged device, wireless charging intensity of the charged device at a present charging position, and displaying, on a display screen, the wireless charging intensity at the present charging position, where the displaying the wireless charging intensity on the display screen is intended to provide a basis for a user to select an optimum charging position.

A charged device includes:

an obtaining unit, configured to obtain wireless charging intensity of the charged device at a present charging position; and

a displaying unit, configured to display the wireless charging intensity at the present charging position after the obtaining unit obtains the wireless charging intensity at the present charging position, where the displaying the wireless charging intensity on a display screen is intended to provide a basis for a user to select an optimum charging position.

A mobile terminal includes: a display module and a wireless charging module, where the wireless charging module includes:

an obtaining subunit, configured to obtain wireless charging intensity of the mobile terminal at a present charging position; and

a displaying subunit, configured to represent the wireless charging intensity in a graphical mode and display the intensity through the display module, after the obtaining subunit obtains the wireless charging intensity at the present charging position.

The embodiments of the present invention use the charged device to obtain the wireless charging intensity of the charged device at the present charging position, and display, on the display screen, the wireless charging intensity at the present charging position, where the displaying the wireless charging intensity on the display screen is intended to provide the basis for the user to select the optimum charging position. As compared with the prior art, by using the wireless charging intensity indication method provided by the embodiments of the present invention, the user may select, from different charging positions, the optimum charging position according to the magnitude of the wireless charging intensity displayed on the display screen of the charged device, thereby improving the efficiency of wireless charging.

### BRIEF DESCRIPTION OF THE DRAWINGS

FIG. 1 is a schematic diagram of an embodiment of a wireless charging intensity indication method according to the present invention;

FIG. 2 is a schematic diagram of another embodiment of a wireless charging intensity indication method according to the present invention;

FIG. 3 is a schematic diagram of an embodiment of a charged device according to the present invention;

FIG. 4 is a schematic diagram of another embodiment of a charged device according to the present invention;

FIG. 5 is a schematic diagram of another embodiment of a charged device according to the present invention;

FIG. 6 is a schematic diagram of another embodiment of a charged device according to the present invention; and

FIG. 7 is a schematic diagram of an embodiment of a mobile terminal according to the present invention.

### DETAILED DESCRIPTION

Embodiments of the present invention provide a wireless charging intensity indication method, so that it is convenient for a user to find an optimum charging position, and the efficiency of wireless charging can be improved. The embodiments of the present invention also provide a corresponding charged device. The embodiments of the present invention are hereinafter described in detail respectively.

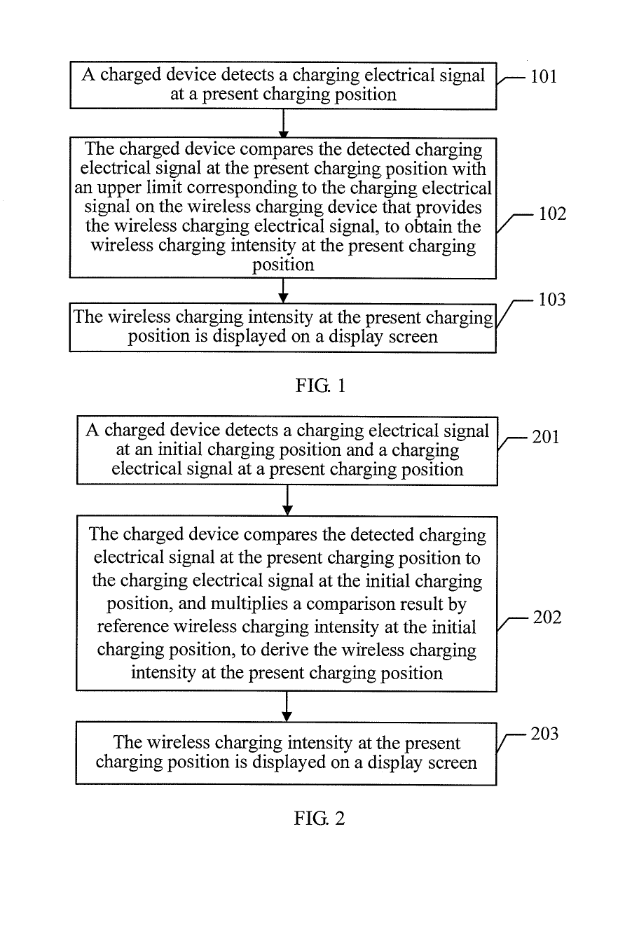

Referring to FIG. 1, an embodiment of a wireless charging intensity indication method according to the present invention includes the following steps:

101. A charged device detects a charging electrical signal at a present charging position.

The wireless charging device charges the charged device after a wireless charging function is enabled. Because the type and shape of the charged device may vary, the optimum wireless charging position with the strongest charging intensity and highest charging efficiency cannot be determined directly. Therefore, after the charged device is placed on the wireless charging device, the charged device detects the charging electrical signal at the present charging position, and according to the charging electrical signal at the present charging position, calculates the charging intensity at the position.

The charging electrical signal includes the charging current, charging voltage, charging power, or change speed of battery capacity of the charged device.

102. The charged device compares the detected charging electrical signal at the present charging position with an upper limit corresponding to the charging electrical signal on the wireless charging device that provides the wireless charging electrical signal, to obtain the wireless charging intensity at the present charging position.

If the charging current at the present charging position is detected in step 101, the charging current at the present charging position is compared with an upper limit of the charging current on the charging device, and the comparison result (e.g., the percentage of the present charging current to the upper limit of the charging current) is regarded as the charging intensity at the present charging position. If it is detected that the charging current at the present charging position is 0.5 A, and the upper limit of the charging current on the charging device is 1 A, 0.5/1=50%, that is, the charging intensity at the present charging position is 50%.

Similarly, if the voltage is detected in step 101, the charging voltage at the present charging position is compared with an upper limit of the charging voltage on the charging device, and the comparison result (e.g., the percentage of the present charging voltage to the upper limit of the charging voltage) is regarded as the charging intensity at the present charging position.

If both the charging current at the present charging position and the charging voltage at the present charging position are detected in step 101, charging power at the present charging position can be calculated, the charging power at the present charging position is compared with an upper limit of the charging power on the charging device, and the comparison result (e.g., the percentage of the present charging power to the upper limit of the charging power) is regarded as the charging intensity at the present charging position.

In addition, the change speed of the battery capacity (that is, the increased battery current within a unit of time) of the charged device in a charging state may also be detected in step 101, the change speed of the battery capacity is compared with an upper limit of the change speed of the battery capacity on the charging device, and the comparison result (e.g., the percentage of the present change speed of the battery capacity to the upper limit of the change speed of the battery capacity) is regarded as the charging intensity at the present charging position.

103. Display the wireless charging intensity at the present charging position on a display screen.

After the wireless charging intensity at the present charging position is calculated in step 102, that is, after the charged device obtains the wireless charging intensity, the wireless charging intensity is displayed on the display screen of the charged device.

On a display interface of the charged device, a small icon may be used to indicate whether the wireless charging function is enabled. By clicking the small icon, or clicking a large wireless charging management icon below, or clicking a corresponding menu item on a user operation menu, the user can view the display interface of the wireless charging intensity, where the displaying the wireless charging intensity may be as follows: the wireless charging intensity at the present charging position is presented on the display screen in a static or dynamic graphical mode.

The static graphical mode includes a scale mode or an incremental column mode. For example, there is an indicator bar on the display interface; the indicator bar, in a state of being filled, identifies the charging intensity; and the specific numerical value of the charging intensity may also be given in a digital form on the indicator bar.

The dynamic graphical mode is a display mode in which a graphic element representative of the charging intensity changes constantly according to the magnitude of the charging intensity. For example, the charging state in the indicator bar rolls from left to right; the leftmost position indicates the present battery capacity; and the rolling speed of the indicator bar may be used to indicate the magnitude of the charging intensity visually, that is, the faster the indicator bar rolls, the stronger the charging intensity is, and vice versa.

It should be noted that the above display mode is merely an example. The indicator bar of the charging intensity may be oval or rectangular, or of other shapes; there may or may not be characters above the indicator bar of the charging intensity; the indicator bar of the charging intensity may be in a horizontal mode or a vertical mode, or in other modes, as long as the charging intensity can be displayed, and the specific display mode of the charging intensity is not limited thereto.

In the embodiment of the present invention, the charged device detects the charging electrical signal at the present charging position, and performs a division operation on the detected charging electrical signal at the present charging position and the upper limit corresponding to the charging electrical signal on the charging device, to derive the wireless charging intensity at the present charging position. After obtaining the wireless charging intensity of the charged device at the present charging position on the wireless charging device, the charged device displays the wireless charging intensity at the present charging position on the display screen. As compared with the prior art, by using the wireless charging intensity indication method provided by the embodiment of the present invention, the user may select, from different charging positions, the optimum charging position according to the magnitude of the charging intensity displayed on the display screen, thereby improving the efficiency of wireless charging.

Referring to FIG. 2, another embodiment of a wireless charging intensity indication method according to the present invention includes the following steps:

201. A charged device detects a charging electrical signal at an initial charging position and a charging electrical signal at a present charging position.

202. The charged device compares the detected charging electrical signal at the present charging position to the charging electrical signal at the initial charging position, and multiplies a comparison result by reference wireless charging intensity at the initial charging position, to derive the wireless charging intensity at the present charging position.

When there is no upper limit value of the charging electrical signal on a charging device, after the charging electrical signal at the initial charging position is detected, the charging electrical signal at the initial charging position is stored; the wireless charging intensity corresponding to the charging electrical signal at the initial charging position is regarded as a reference value of the wireless charging intensity (e.g., 50%); a division operation is performed on the charging electrical signal at the present charging position and the charging electrical signal at the initial charging position, to derive a calculation result; and the calculation result is multiplied by the reference value of the wireless charging intensity, to derive the wireless charging intensity at the present charging position. For example, the charging current at the initial charging position is 0.5 A, and the reference value of the charging intensity is 50%. After the charged device is moved to another position, it is detected that the current intensity at the present charging position is 0.6 A, and it is derived through calculation that the current intensity at the present charging position is 60%.

203. Display the wireless charging intensity at the present charging position on a display screen.

After obtaining the wireless charging intensity of the charged device at the present charging position, the charged device displays the wireless charging intensity on the display screen.

In the embodiment of the present invention, if there is no upper limit value of the charging electrical signal on the charging device, the charged device is used to detect the charging electrical signal at the present charging position; perform the division operation on the detected charging electrical signal at the present charging position and the charging electrical signal at the initial charging position, to derive the calculation result; multiply the calculation result by the reference value of the wireless charging intensity corresponding to the initial charging position, to derive the wireless charging intensity at the present charging position; and after obtaining the wireless charging intensity of the charged device at the present charging position on the wireless charging device, display the wireless charging intensity at the present charging position on the display screen. As compared with the prior art, by using the wireless charging intensity indication method provided by the embodiment of the present invention, a user may select, from different charging positions, the optimum charging position according to the magnitude of the charging intensity displayed on the display screen, thereby improving the efficiency of wireless charging.

For better understanding, a specific application scenario is taken as an example hereinafter to describe the wireless charging intensity indication method of the present invention in detail.

When a charged device (a mobile phone is taken as an example in this application scenario) is placed on the wireless charging device, the mobile phone obtains a charging current of 0.3 A at a first charging position, and as the upper limit of the charging current on the wireless charging device is 1 A, performs a division operation on the charging current at the first charging position of the mobile phone and the upper limit of the charging current on the wireless charging device, to derive that the percentage of the calculation result is 30%, that is, the wireless charging intensity is 30%. When the mobile phone is moved horizontally on the wireless charging device, the mobile phone obtains a charging current of 0.5 A at a second charging position, and compares 0.5 A with 1 A, to derive that the percentage of the comparison result is 50%, that is, the wireless charging intensity is 50%. When the mobile phone is rotated by an angle at the second charging position, it may be considered that the mobile phone is moved to a third charging position, and the mobile phone obtains a charging current of 0.7 A at the third charging position, and compares 0.7 A with 1 A, to derive that the percentage of the comparison result is 70%, that is, the wireless charging intensity is 70%. The optimum charging position is determined as the third charging position according to the wireless charging intensity indication. The user may also move the mobile phone to some other positions, and find the position where the charging intensity is the strongest to implement wireless charging, thereby improving the efficiency of wireless charging.

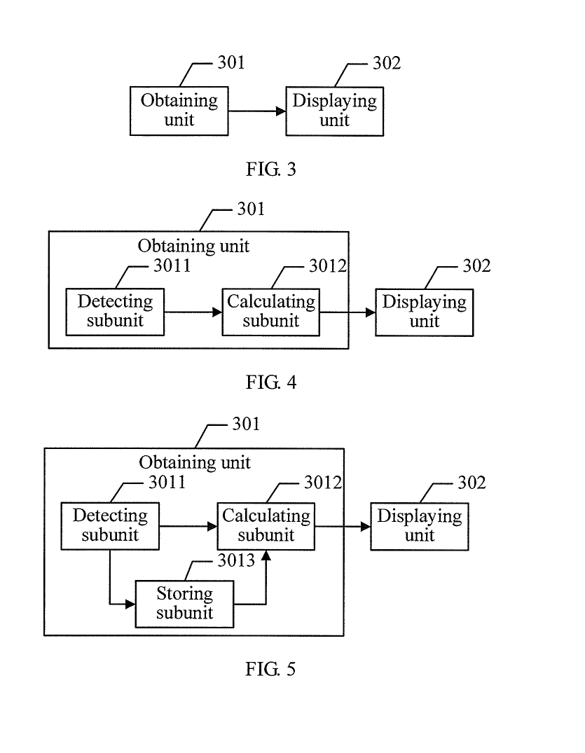

Referring to FIG. 3, an embodiment of a charged device according to the present invention includes: an obtaining unit 301 and a displaying unit 302.

The obtaining unit 301 is configured to obtain wireless charging intensity of the charged device at a present charging position.

The displaying unit 302 is configured to display the wireless charging intensity at the present charging position after the obtaining unit 301 obtains the wireless charging intensity at the present charging position, where the displaying the wireless charging intensity on a display screen is intended to provide a basis for a user to select an optimum charging position.

In the embodiment of the present invention, after the obtaining unit 301 obtains the wireless charging intensity of the charged device at the present charging position, the displaying unit 302 displays the wireless charging intensity at the present charging position, where the displaying the wireless charging intensity on the display screen is intended to provide the basis for the user to select the optimum charging position. As compared with the prior art, by using the wireless charging intensity indication method provided by the embodiment of the present invention, the user may select, from different positions, the optimum charging position according to the magnitude of the charging intensity displayed on the display screen, thereby improving the efficiency of wireless charging.

Based on the above embodiment corresponding to FIG. 3, referring to FIG. 4, the obtaining unit 301 according to an embodiment of the present invention includes a detecting subunit 3011 and a calculating subunit 3012.

The detecting subunit 3011 is configured to detect a charging electrical signal at the present charging position.

The calculating subunit 3012 is configured to, after the detecting subunit 3011 detects the charging electrical signal at the present charging position, compare the detected charging electrical signal at the present charging position with an upper limit corresponding to the charging electrical signal on a wireless charging device that provides the wireless charging electrical signal, to obtain the wireless charging intensity at the present charging position.

In the embodiment of the present invention, the detecting subunit 3011 detects the charging electrical signal at the present charging position, and the calculating subunit 3012 performs a division operation on the detected charging electrical signal at the present charging position and the upper limit corresponding to the charging electrical signal on the wireless charging device, to obtain the wireless charging intensity at the present charging position. After the obtaining unit 301 obtains the wireless charging intensity of the charged device at the present charging position on the wireless charging device, the displaying unit 302 displays the wireless charging intensity at the present charging position. As compared with the prior art, by using the wireless charging intensity indication method provided by the embodiment of the present invention, the user may select, from different positions, the optimum charging position according to the magnitude of the charging intensity displayed on the display screen, thereby improving the efficiency of wireless charging.

Based on the above embodiment corresponding to FIG. 3, referring to FIG. 5, the obtaining unit 301 in an embodiment of the present invention also includes the detecting subunit 3011, the calculating subunit 3012, and a storing subunit 3013.

The detecting subunit 3011 is configured to detect a charging electrical signal at an initial charging position and the charging electrical signal at the present charging position.

The calculating subunit 3012 is also configured to, after the detecting subunit 3011 detects the charging electrical signal at the present charging position, compare the detected charging electrical signal at the present charging position to the charging electrical signal at the initial charging position, and multiply a comparison result by reference wireless charging intensity at the initial charging position, to obtain the wireless charging intensity at the present charging position.

The storing subunit 3013 is configured to store the charging electrical signal at the initial charging position after the detecting subunit 3011 detects the charging electrical signal at the initial charging position, when the present charging position is the initial charging position.

In the embodiment of the present invention, after the detecting subunit 3011 detects the charging electrical signal at the initial charging position, the storing subunit 3013 stores the charging electrical signal at the initial charging position. After the charged device is moved to another position, the detecting subunit 3011 detects the charging electrical signal at the present charging position; and the calculating unit 3012 compares the detected charging electrical signal at the present charging position to the charging electrical signal at the initial charging position, and multiplies the comparison result by the reference wireless charging intensity at the initial charging position, to obtain the wireless charging intensity at the present charging position. After the obtaining unit 301 obtains the wireless charging intensity of the charged device at the present charging position on the wireless charging device, the displaying unit 302 displays the wireless charging intensity at the present charging position. As compared with the prior art, by using the charged device provided by the embodiment of the present invention, the user may select, from different positions, the optimum charging position according to the magnitude of the charging intensity displayed on the display screen, thereby improving the efficiency of wireless charging.

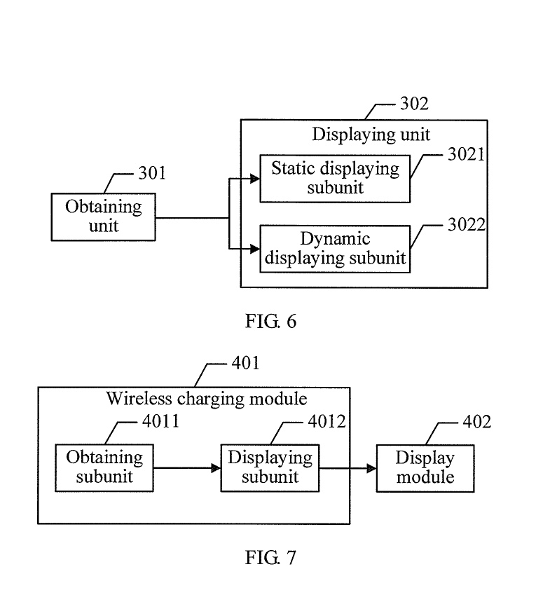

Referring to FIG. 6, based on any one of the above embodiments in FIGS. 3 to 5, the displaying unit 302 in an embodiment of the present invention includes a static displaying subunit 3021 and a dynamic displaying subunit 3022.

The static displaying subunit 3021 is configured to present, on the display screen in a static graphical mode, the wireless charging intensity at the present charging position.

The dynamic displaying subunit 3022 is configured to present, on the display screen in a dynamic graphical mode, the wireless charging intensity at the present charging position.

The static graphical mode includes a scale mode or an incremental column mode, and the dynamic graphical mode is a display mode in which a graphic element representative of the charging intensity changes constantly according to the magnitude of the charging intensity.

In the embodiment of the present invention, after the obtaining unit 301 obtains the wireless charging intensity, the static displaying subunit 3021 in the displaying unit 302 may present the wireless charging intensity on the display screen in the static graphical mode, and the dynamic displaying subunit may present the wireless charging intensity on the display screen in the dynamic graphical mode. As compared with the prior art, by using the wireless charging intensity indication method provided by the embodiment of the present invention, the user may select, from different positions, the optimum charging position according to the magnitude of the charging intensity displayed on the display screen, thereby improving the efficiency of wireless charging.

Referring to FIG. 7, an embodiment of a mobile terminal according to the present invention includes: a display module 402 and a wireless charging module 401. The wireless charging module includes:

an obtaining subunit 4011, configured to obtain wireless charging intensity of the mobile terminal at a present charging position; and

a displaying subunit 4012, configured to represent the wireless charging intensity in a graphical mode and display the intensity through the display module 402, after the obtaining subunit 4011 obtains the wireless charging intensity at the present charging position.

By using the mobile terminal in the embodiment of the present invention, the obtaining subunit 4011 in the wireless charging module 401 obtains the wireless charging intensity of the mobile terminal at the present charging position, and the displaying subunit 4012 represents the wireless charging intensity in a graphical mode and displays the intensity through the display module 402. By using the mobile terminal provided by the embodiment of the present invention, a user may select, from different positions, the optimum charging position according to the magnitude of the charging intensity displayed on the display module, thereby improving the efficiency of wireless charging.

The mobile terminal may be a mobile phone, a tablet computer, a notebook computer, an MP3 player, an MP4 player, a digital photo frame, a digital camera, a projection device, a set-top box, a flat panel TV, a display, a speaker, an interphone, a navigator, a game machine, a mouse, and the like.

Persons of ordinary skill in the art may understand that all or part of the steps of the method according to the above embodiments may be implemented by a program instructing relevant hardware. The program may be stored in a computer readable storage medium. The storage medium may include a ROM, a RAM, a magnetic disk, or a CD-ROM, and the like.

The wireless charging intensity indication method and the charged device provided by the embodiments of the present invention are hereinbefore described in detail. Although the principle and implementation of the present invention are described in detail with reference to exemplary embodiments herein, the description of the above embodiments is merely used to help understand the method and the core idea of the present invention. In addition, persons of ordinary skill in the art can make some variations with respect to the implementation and applicability according to the idea of the present invention. To sum up, the specification should not be construed as limitations on the present invention.

What is claimed is:

1. A wireless charging intensity indication method, comprising:
obtaining, by a charged device, wireless charging electrical signal intensity of the charged device at a present charging position, and
displaying, on a display screen of the charged device, the wireless charging electrical signal intensity at the present charging position, wherein the displaying the wireless charging electrical signal intensity on the display screen is intended to provide a basis for a user to select an charging position.

2. The wireless charging intensity indication method according to claim 1, wherein the obtaining, by the charged device, the wireless charging electrical signal intensity of the charged device at the present charging position comprises:
detecting, by the charged device, the charging electrical signal at the present charging position; and
comparing, by the charged device, the detected charging electrical signal at the present charging position with an upper limit corresponding to the charging electrical signal on a wireless charging device that provides the wireless charging electrical signal, to obtain the wireless charging intensity at the present charging position.

3. The wireless charging intensity indication method according to claim 1, wherein the obtaining, by the charged device, the wireless charging electrical signal intensity of the charged device at the present charging position comprises:
detecting, by the charged device, a charging electrical signal at an initial charging position and the charging electrical signal at the present charging position; and
comparing, by the charged device, the detected charging electrical signal at the present charging position to the charging electrical signal at the initial charging position, and multiplying a comparison result by reference wireless charging electrical signal intensity at the initial charging position, to obtain the wireless charging electrical signal intensity at the present charging position.

4. The wireless charging intensity indication method according to claim 3, wherein after the detecting, by the charged device, the charging electrical signal at the initial charging position, the method further comprises:
storing, by the charged device, the charging electrical signal at the initial charging position.

5. The wireless charging intensity indication method according to claim 2, wherein the charging electrical signal comprises a charging current, charging voltage, charging power, or change speed of battery capacity of the charged device.

6. The wireless charging intensity indication method according to claim 1, wherein the displaying, on the display screen, the wireless charging intensity at the present charging position comprises:
presenting, on the display screen in a static or dynamic graphical mode, the wireless charging intensity at the present charging position.

7. The wireless charging intensity indication method according to claim 6, wherein the static graphical mode comprises a scale mode or an incremental column mode, and the dynamic graphical mode is a display mode in which a graphic element representative of the charging intensity changes constantly according to a magnitude of the charging intensity.

8. A charged device, comprising:
an obtaining unit, configured to obtain wireless charging electrical signal intensity of the charged device at a present charging position; and
a displaying unit, configured to display the wireless charging electrical signal intensity at the present charging position after the obtaining unit obtains the wireless charging electrical signal intensity at the present charging position, wherein the displaying the wireless charging electrical signal intensity on a display screen is intended to provide a basis for a user to select an optimum charging position.

9. The charged device according to claim 8, wherein the obtaining unit comprises:
a detecting subunit, configured to detect the charging electrical signal at the present charging position; and
a calculating subunit, configured to, after the detecting subunit detects the charging electrical signal at the present charging position, compare the detected charging electrical signal at the present charging position with an upper limit corresponding to the charging electrical signal on a wireless charging device that provides the wireless charging electrical signal, to obtain the wireless charging electrical signal intensity at the present charging position.

10. The charged device according to claim 8, wherein the obtaining unit comprises:
a detecting subunit, configured to detect a charging electrical signal at an initial charging position and the charging electrical signal at the present charging position; and
a calculating subunit, configured to, after the detecting subunit detects the charging electrical signal at the present charging position, compare the detected charging electrical signal at the present charging position to the charging electrical signal at the initial charging position, and multiply a comparison result by reference wireless charging electrical signal intensity at the initial charging position, to obtain the wireless charging intensity at the present charging position.

11. The charged device according to claim 10, wherein the obtaining unit further comprises:
a storing subunit, configured to store the charging electrical signal at the initial charging position after the detecting subunit detects the charging electrical signal at the initial charging position, when the present charging position is the initial charging position.

12. The charged device according to claim 9, wherein the charging electrical signal comprises a charging current, charging voltage, charging power, or change speed of battery capacity of the charged device.

13. The charged device according to claim 8, wherein the displaying unit comprises:
a static displaying subunit, configured to present, on the display screen in a static graphical mode, the wireless charging electrical signal intensity at the present charging position; and
a dynamic displaying subunit, configured to present, on the display screen in a dynamic graphical mode, the wireless charging electrical signal intensity at the present charging position.

14. The charged device according to claim 13, wherein the static graphical mode comprises a scale mode or an incremental column mode, and the dynamic graphical mode is a display mode in which a graphic element representative of the charging intensity changes constantly according to a magnitude of the charging intensity.

15. A mobile terminal, comprising a display module and a wireless charging module, wherein the wireless charging module comprises:
an obtaining subunit, configured to obtain wireless charging intensity of the mobile terminal at a present charging position; and
a displaying subunit, configured to represent the wireless charging intensity in a graphical mode and display the intensity through the display module, after the obtaining subunit obtains the wireless charging intensity at the present charging position.
